(19) United States
(12) Patent Application Publication
(10) Pub. No.: US 2026/0327798 A1
(43) Pub. Date: Oct. 22, 2026

(54) GAS FLOW PATHS FOR SUBSTRATE PROCESSING CHAMBERS, AND RELATED APPARATUS

(71) Applicant: Applied Materials, Inc., Santa Clara, CA (US)

(72) Inventors: Aditya CHUTTAR, Santa Clara, CA (US); Muhannad MUSTAFA, Milpitas, CA (US); Geetika BAJAJ, Cupertino, CA (US); Shashidhara PATEL H B, Bangalore (IN); Kevin S. GRIFFIN, Santa Clara, CA (US); Yi XU, San Jose, CA (US); Amit SAHU, Bangalore (IN); Nagaraj NAIK, Bangalore (IN); Seshadri GANGULI, Santa Clara, CA (US); Yixiong YANG, Fremont, CA (US); Rakesh RAMADAS, Santa Clara, CA (US); Srinivas GANDIKOTA, Santa Clara, CA (US); Prahallad L. IYENGAR, Santa Clara, CA (US); Jing ZHENG, Santa Clara, CA (US); Sanjeev BALUJA, Campbell, CA (US)

(21) Appl. No.: 19/366,304

(22) Filed: Oct. 22, 2025

(30) Foreign Application Priority Data
Apr. 17, 2025 (IN) 202541037269

(51) Int. Cl. C23C 16/455; C23C 16/458

(52) U.S. Cl. CPC C23C 16/45544; C23C 16/45565; C23C 16/4557; C23C 16/458

(57) ABSTRACT

A processing chamber includes a showerhead and a lid plate coupled thereto. A first annular channel disposed around the lid plate is coupled to an exhaust conduit. A second annular channel is disposed around at least one of the lid plate or the showerhead. The second annular channel is coupled to a supply of purge gas.

### CROSS-REFERENCE TO RELATED APPLICATION

This application claims the benefit of India patent application serial number 202541037269, filed Apr. 17, 2025, which is herein incorporated by reference in its entirety.

### BACKGROUND

### Field

Embodiments of the present disclosure generally relate to substrate processing chambers.

### Description of the Related Art

The manufacture of semiconductor devices involves the deposition of materials onto a substrate. In a typical deposition process, a precursor gas is introduced into a processing chamber containing the substrate, and reacts with the substrate. In some examples, such as in atomic layer deposition, a layer of atoms is deposited on reactive sites on the surface of the substrate. The reaction proceeds until the surface is covered with the precursor, and then ends as atoms bond with each reactive site. Remaining precursor gas is purged out of the processing chamber, then a different precursor is introduced into the processing chamber to create new reactive sites on the deposited layer. Such deposition processes typically include several repetitions of the introduction, reaction, and purge sequence, alternating between each precursor.

At each iteration, if the concentration of the precursor material is too low, an insufficient amount of material may be deposited, or the deposition of the material may take longer than expected. However, if the concentration of the precursor material is too high, then excessive precursor material may be wasted when being purged out of the processing chamber. The effectiveness of the purge operation depends on the rapid removal of the precursor gas from the processing chamber. Processing chambers include space to facilitate the transfer of a substrate, such as space to enable a substrate support to be raised and lowered. Such space typically fills with the precursor gas, and must be flushed during each purge operation. The larger the space, the longer the duration of the purge operation, and the greater the amount of the precursor gas that is wasted. Longer operations and the wasting of precursor gas adversely affect the time and cost of a processing operation.

Thus, there is a need for improved processing chamber designs that address the above shortcomings.

### SUMMARY

The present disclosure generally relates to substrate processing chambers.

In one or more embodiments, a processing chamber includes a chamber body, including a floor and one or more chamber sidewalls, and a showerhead coupled to the chamber body, the showerhead and chamber body enclosing a processing volume. A lid plate is coupled to the showerhead, the lid plate and the showerhead defining a plenum therebetween. A first annular channel is disposed around the lid plate; the first annular channel being coupled to an exhaust conduit. A second annular channel is disposed around at least one of the lid plate or the showerhead; the second annular channel being coupled to a supply of purge gas.

In one or more embodiments, a processing chamber includes a chamber body, including a floor and one or more chamber sidewalls, and a showerhead coupled to the chamber body, the showerhead and chamber body enclosing a processing volume. A substrate support is disposed in the processing volume. A shaft is coupled to the substrate support, and extends through the floor. A bellows assembly is disposed around the shaft in the processing volume. The bellows assembly includes a first bellows sidewall disposed closer to the one or more chamber sidewalls than to the shaft.

In one or more embodiments, a processing chamber includes a chamber body, including a floor and one or more chamber sidewalls. The processing chamber further includes a lid assembly that includes a lid plate coupled to the chamber body. The lid assembly further includes a compartment disposed on the lid plate, the compartment including one or more compartment sidewalls and a ceiling. A first manifold is disposed in the compartment. A first gas reservoir is disposed in the compartment, and is fluidically coupled to the first manifold.

In one or more embodiments, a gas mixer for a substrate processing chamber includes a first mixer unit. The first mixer unit includes a first annular channel surrounding a first conduit, and a plurality of first ducts fluidically coupling the first annular channel with the first conduit. Each first duct is oriented to direct a first gas flow from the first annular channel into the first conduit in a clockwise direction about a center of the first conduit. The gas mixer further includes a second mixer unit. The second mixer unit includes a second annular channel surrounding a second conduit. The second conduit is aligned with the first conduit. The second mixer unit further includes a plurality of second ducts fluidically coupling the second annular channel with the second conduit. Each second duct is oriented to direct a second gas flow from the second annular channel into the second conduit in an anticlockwise direction about a center of the second conduit.

In one or more embodiments, a processing chamber includes a chamber body, including a floor and one or more chamber sidewalls, and a showerhead coupled to the chamber body, the showerhead and chamber body enclosing a processing volume. A lid plate is coupled to the showerhead. The lid plate and the showerhead define a plenum therebetween. A gas mixer is coupled to the lid plate, and includes a first mixer unit. The first mixer unit includes a first annular channel surrounding a first conduit, and a plurality of first ducts fluidically coupling the first annular channel with the first conduit. Each first duct is oriented to direct a first gas flow from the first annular channel into the first conduit in a clockwise direction about a center of the first conduit. The gas mixer further includes a second mixer unit. The second mixer unit includes a second annular channel surrounding a second conduit. The second conduit is aligned with the first conduit. The second mixer unit further includes a plurality of second ducts fluidically coupling the second annular channel with the second conduit. Each second duct is oriented to direct a second gas flow from the second annular channel into the second conduit in an anticlockwise direction about a center of the second conduit.

In one or more embodiments, an edge ring for a substrate processing chamber includes an annular body including a top surface and a bottom surface. The edge ring further includes a skirt extending downwardly from the bottom surface of the annular body. The skirt includes an outwardly extending first step. A level of a top surface of the first step is below a level of the top surface of the annular body.

In one or more embodiments, an assembly for a substrate processing chamber includes an edge ring. The edge ring includes an annular body including a top surface and a bottom surface, and a skirt extending downwardly from the bottom surface. The skirt includes an outwardly extending first step. The assembly further includes a liner that includes a sleeve and a first ledge extending inwardly from the sleeve. The first ledge at least partially overlaps the first step.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 schematically illustrates a cross-section of a processing chamber.

FIG. 1A schematically illustrates flow paths of gases in a portion of the processing chamber of FIG. 1.

FIG. 2 schematically illustrates an embodiment of a component of the processing chamber of FIG. 1.

FIG. 3 schematically illustrates a top view cross-section of a lid assembly that may be incorporated in the processing chamber of FIG. 1.

FIG. 4 schematically illustrates a side view cross-section of the lid assembly of FIG. 3.

FIG. 5A schematically illustrates a typical result of a deposition operation conducted in a conventional processing chamber.

FIG. 5B schematically illustrates a result of a deposition operation conducted in the processing chamber of FIG. 1 incorporating the lid assembly of FIGS. 3 and 4.

FIG. 6 schematically illustrates a mixer for process gases that may be incorporated in the processing chamber of FIG. 1.

FIGS. 7A to 7C schematically illustrate gas flow through units of the mixer of FIG. 6.

FIG. 8 schematically illustrates a portion of an edge ring and a liner that may be used in the processing chamber of FIG. 1.

FIG. 9 schematically illustrates a portion of another embodiment of an edge ring and a liner that may be used in the processing chamber of FIG. 1.

FIG. 9A is an enlargement of a portion of FIG. 9.

To facilitate understanding, identical reference numerals have been used, where possible, to designate identical elements that are common to the figures. One or more elements or features of any one embodiment or example may be beneficially incorporated in any one or more other non-mutually exclusive embodiments or examples.

### DETAILED DESCRIPTION

The present disclosure concerns substrate processing chambers. In particular, embodiments in the present disclosure concern processing chambers and associated components that are configured for the performance of atomic layer deposition (“ALD”) processes. Nevertheless, the processing chambers and associated components of the present disclosure can be configured as any one or more of an ALD chamber, chemical vapor deposition (CVD) chamber, physical vapor deposition (PVD) chamber, etch chamber, degas chamber, an ion implantation chamber, ashing chamber, cleaning chamber, a thermal processing chamber (e.g., rapid thermal processing, anneal, cool down, thermal management control), a plasma processing chamber, or other type of substrate processing chamber.

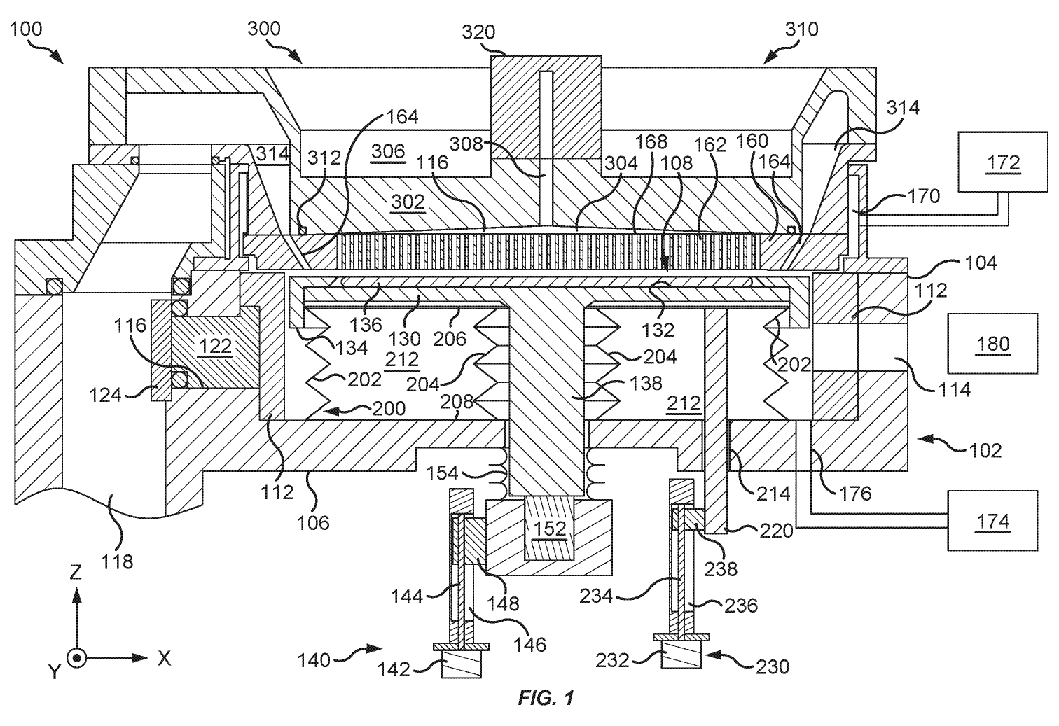

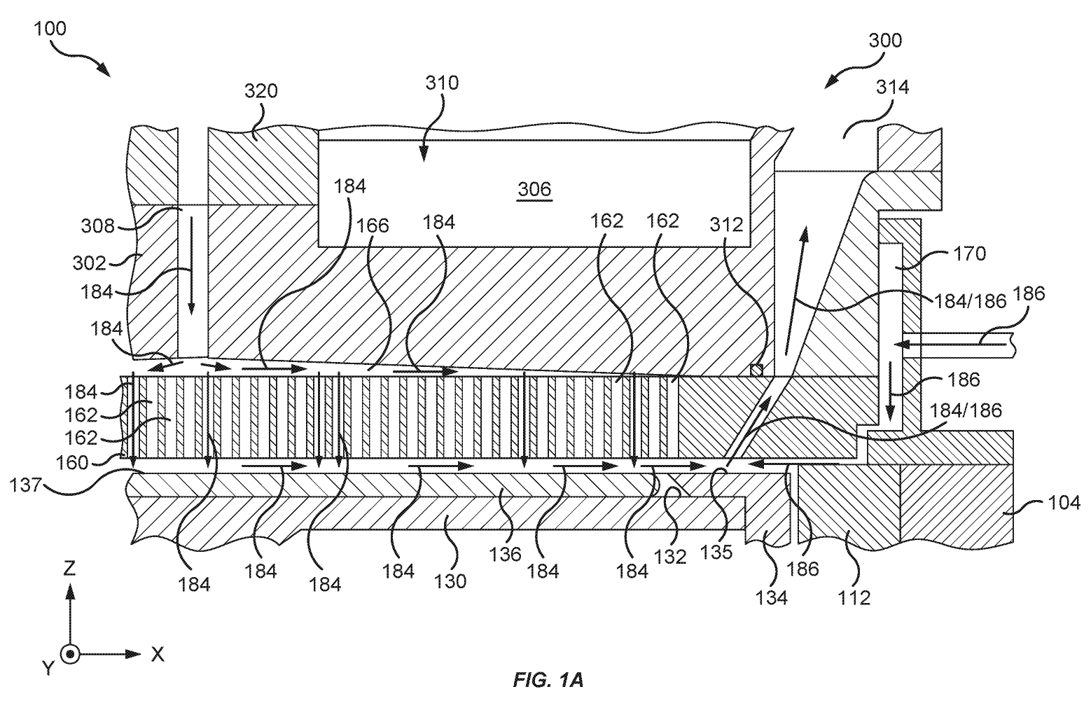

FIG. 1 schematically illustrates a cross-section of a processing chamber 100. The processing chamber 100 includes a chamber body 102 having one or more chamber sidewalls 104 and a floor 106 forming boundaries of a processing volume 108. In some embodiments that may be combined with other embodiments, one or more liners 112 are disposed in the processing volume 108. The one or more liners 112 may be made of a ceramic material, such as an aluminum oxide, aluminum nitride, or silicon carbide. Substrates enter and exit the processing chamber 100 through an access port 114 at one of the chamber sidewalls 104.

In some embodiments that may be combined with other embodiments, one or more exhaust vents 116 in one of the chamber sidewalls 104 fluidically couple the processing volume 108 with an exhaust conduit 118. As illustrated, in some examples, the one or more exhaust vents 116 are blocked by a plug 122. In other examples, the plug 122 is omitted. Additionally, or alternatively, in some examples, the one or more exhaust vents116 are blocked by a cap 124. In other examples, the cap 124 is omitted. In some embodiments that may be combined with other embodiments, the one or more exhaust vents 116 are omitted.

A substrate support 130, such as a susceptor or a pedestal, is disposed in the processing volume 108. The substrate support 130 may be metallic (e.g., a stainless steel), or may be made of a ceramic material, such as an aluminum oxide, aluminum nitride, or silicon carbide. A substrate 136 is shown disposed on a support surface 132 of the substrate support 130. The substrate support 130 is coupled to a shaft 138. The shaft 130 extends through the floor 106, and is coupled to an actuator 140 that raises and lowers the substrate support 130 along the Z direction. In some examples that may be combined with other examples, the actuator 140 includes a motor 142, such as a stepper motor, that rotates a lead screw 144 that is disposed in a channel 146. A follower 148 is engaged with the lead screw 144, and is coupled to the shaft 138. Rotation of the lead screw 144 by the motor 142 causes the follower 148 to move along the channel 146, and so raises or lowers the shaft 138 and the substrate support 130 accordingly. In some examples that may be combined with other examples, the actuator 140 includes a piston coupled to the follower 148. In some embodiments that may be combined with other embodiments, the shaft 138 is coupled to another actuator 152, such as a motor, that rotates the substrate support 130 about the Z direction in the X-Y plane. A shaft bellows 154 coupled to the processing chamber 100 (e.g., at the floor 106) surrounds the portion of the shaft 138 that extends below the processing chamber 100 to separate the environment internal to the processing chamber 100 from the environment external to the processing chamber 100.

In some embodiments that may be combined with other embodiments, the substrate support 130 includes a chucking electrode. In some embodiments that may be combined with other embodiments, the substrate support 130 includes a heater. In some embodiments that may be combined with other embodiments, the substrate support 130 includes coolant channels for flowing a cooling fluid, such as a glycol (e.g., ethylene glycol). As illustrated, in some embodiments that may be combined with other embodiments, an edge ring 134 is disposed on the substrate support 130. In some embodiments that may be combined with other embodiments, any one or more of the heater, the chucking electrode, the coolant channels, or the edge ring 134 may be omitted.

A bellows assembly 200 is disposed around the shaft 138 in the processing volume 108. The bellows assembly 200 includes an outer bellows sidewall 202 that is disposed closer to the one or more chamber sidewalls 104 than to the shaft 138. The bellows assembly 200 includes an inner bellows sidewall 204 between the shaft 138 and the outer bellows sidewall 202. The outer bellows sidewall 202 and the inner bellows sidewall 204 are coupled to a top plate 206.

In some embodiments that may be combined with other embodiments, the outer bellows sidewall 202 and the inner bellows sidewall 204 are sealingly coupled to the floor 106. In some examples, the outer bellows sidewall 202 and the inner bellows sidewall 204 are coupled to a bottom plate 208 that is sealingly coupled to the floor 106. In some other examples, the bottom plate 208 is omitted, and the outer bellows sidewall 202 and the inner bellows sidewall 204 are sealingly coupled directly to the floor 106.

The top plate 206 is annular, and the bottom plate 208 (if present) is annular. The top plate 206, outer bellows sidewall 202, and inner bellows sidewall 204 encompass a bellows volume 212 that is annular, such as donut-shaped. The bellows volume 212 is fluidically isolated from the processing volume 108. In some examples, a first fluid in the processing volume 108 is fluidically isolated from a second fluid in the bellows volume 212 by the bellows assembly 200. In some embodiments that may be combined with other embodiments, the bellows volume 212 is fluidically coupled to the environment external to the processing chamber 100 by a bellows vent 214.

The top plate 206 is movable along the Z direction with respect to the floor 106 to expand and contract the bellows assembly 200. In some embodiments that may be combined with other embodiments, movement of the substrate support 130 along the Z direction causes movement of the top plate 206 along the Z direction. In some examples, the top plate 206 is coupled to at least one of the substrate support 130 or the shaft 138. In some examples that may be combined with other examples, the top plate 206 is not coupled to the substrate support 130. In some examples that may be combined with other examples, the top plate 206 is not coupled to the shaft 138.

In some embodiments that may be combined with other embodiments, the top plate 206 is movable along the Z direction independently of movement of the substrate support 130 along the Z direction. In some examples, the top plate 206 is coupled via a bellows shaft 220 to an actuator 230 that moves the top plate 206 along the Z direction. In some of such examples, the bellows shaft 220 extends from the top plate 206 through the bellows volume 212 and the bellows vent 214 to the actuator 230. In some examples that may be combined with other examples, the actuator 230 includes a motor 232, such as a stepper motor, that rotates a lead screw 234 that is disposed in a channel 236. A follower 238 is engaged with the lead screw 234, and is coupled to the bellows shaft 220. Rotation of the lead screw 234 by the motor 232 causes the follower 238 to move along the channel 236, and so raises or lowers the bellows shaft 220 and the top plate 206 accordingly. In some examples that may be combined with other examples, the actuator 230 includes a piston coupled to the follower 238.

In embodiments in which the top plate 206 is moved along the Z direction by movement of the substrate support 130, the bellows shaft 220, the actuator 230, and the bellows vent 214 in the floor 106 may be omitted.

As illustrated, the bellows assembly 200 (when expanded, as shown) occupies a majority of the space in the processing volume 108. Compared to conventional processing chambers, the space in the processing volume 108 into which process gases can migrate is relatively small in the processing chamber 100. Use of the bellows assembly 200 in the processing chamber 100 can mitigate waste of process gases and can reduce the time taken for purging compared to conventional processing chambers.

A showerhead 160 is coupled to the chamber body 102. The showerhead 160, the one or more chamber sidewalls 104, and the floor 106 encloses the processing volume 108. A lid assembly 300 is coupled to the showerhead 160. The lid assembly 300 includes a lid plate 302 disposed above the showerhead 160. As illustrated, in some embodiments that may be combined with other embodiments, the lid plate 302 includes a recess 306. The recess 306 at least partially defines a compartment 310 of the lid assembly 300. A gas mixer 320 is disposed on the lid plate 302 in the compartment 310. A conduit 308 through the lid plate 302 conveys process gases from the gas mixer 320 to a plenum 166 between the lid plate 302 and the showerhead 160. As illustrated, in some embodiments that may be combined with other embodiments, the plenum 166 is defined at least in part by an upper surface 168 of the showerhead 160 and a lower surface 304 of the lid plate 302. Alternatively, in some embodiments that may be combined with other embodiments, the plenum 166 is at least in part defined by the upper surface 168 of the showerhead 160 and a lower surface of a diffuser plate disposed between the showerhead 160 and the lid plate 302.

As illustrated, in some embodiments that may be combined with other embodiments, the lower surface 304 of the lid plate 302 is shaped such that a distance between the upper surface 168 of the showerhead 160 and the lower surface 304 of the lid plate 302 is greater at a central portion of the lid plate 302 than at a peripheral portion of the lid plate 302. In some examples, a seal 312 (such as an o-ring) at the peripheral portion of the lid plate 302 contacts the lid plate 302 and the showerhead 160.

An exhaust channel 314 is disposed around the lid plate 302. As illustrated, in some embodiments that may be combined with other embodiments, the exhaust channel 314 is annular. The seal 312 fluidically isolates the plenum 166 from the exhaust channel 314. The exhaust channel 314 is fluidically coupled to the exhaust conduit 118. In some embodiments that may be combined with other embodiments, the exhaust conduit 118 is coupled to a vacuum system.

The showerhead 160 includes a plurality of first apertures 162 and a plurality of second apertures 164. The plurality of first apertures 162 fluidically couples the plenum 166 and the processing volume 108. In some embodiments that may be combined with other embodiments, a size and/or a distribution of the first apertures 162 is varied across the showerhead 160 in order to affect a flow distribution of gas through the showerhead 160. In some examples, the size and/or distribution of the first apertures 162 is varied across the showerhead 160 in order to facilitate an even distribution of gas across the substrate 136.

The plurality of second apertures 164 fluidically couples the processing volume 108 and the exhaust channel 314. The plurality of second apertures 134 surrounds the plurality of first apertures 132. The seal 312 is disposed between the plurality of first apertures 132 and the plurality of second apertures 134.

A purge channel 170 is disposed around the exhaust channel 314. As illustrated, in some embodiments that may be combined with other embodiments, the purge channel 170 is annular. The purge channel 170 is fluidically coupled to a source 172 of purge gas, such as N₂, Ar, or He.

In some embodiments that may be combined with other embodiments, another source 174 of purge gas (such as N₂, Ar, or He) is fluidically coupled to the processing volume 108 via a purge port 176 in the chamber body 102. As illustrated, in some examples, the purge port 176 is in the floor 106. In other examples, the purge port 176 is in one of the one or more chamber sidewalls 104. In some embodiments that may be combined with other embodiments, the purge port 176 and the source 174 of purge gas are omitted.

In some embodiments that may be combined with other embodiments, operation of the processing chamber is controlled by a controller 180. The controller 180 includes a central processing unit (CPU), a memory containing instructions, and support circuits for the CPU. The memory, or non-transitory computer readable medium, is one or more of a readily available memory such as random access memory (RAM), read only memory (ROM), floppy disk, hard disk, flash drive, or any other form of digital storage, local or remote. The support circuits are coupled to the CPU for supporting the CPU. The support circuits include cache, power supplies, clock circuits, input/output circuitry and subsystems, and the like. Operations and operating parameters are stored in the memory as a software routine that is executed or invoked to configure the controller 180 into a specific purpose controller to control the operations of the processing chamber 100. The controller 180 is configured to conduct one or more of the operations described herein. The instructions stored on the memory, when executed, cause one or more of the operations described herein to be conducted.

The controller 180 includes, or is coupled to, a transmitter/receiver that facilitates communication with other devices, such as a base station or other controllers of other processing chambers or other systems.

FIG. 1A schematically illustrates flow paths of gases across a portion of the substrate 136 in the processing chamber 100. The flow of a first gas, such as a process gas or a purge gas, is depicted by arrows 184. The first gas 184 flows from the gas mixer 320 through the conduit 308 in the lid plate 302, and into the plenum 166. The first gas 184 flows through the first apertures 162 of the showerhead 160 into the processing volume 108, and across an upper surface 137 of the substrate 136 towards the second apertures 164 of the showerhead 160.

The flow of a second gas, such as a purge gas, is depicted by arrows 186. The second gas 186 flows from the purge gas source (172, FIG. 1) into the purge channel 170. The second gas 186 flows from the purge channel 170 through one or more purge ports 176 into the processing volume 108. The second gas 186 flows towards the second apertures 164 of the showerhead 160. As illustrated, in some embodiments that may be combined with other embodiments, the second gas 186 flows across at least a portion of an upper surface 135 of the edge ring 134 towards the second apertures 164 of the showerhead 160.

In some embodiments that may be combined with other embodiments, the second gas 186 acts as a buffer that hinders migration of the first gas 184 around the edge ring 134 towards the floor 106 of the processing chamber 100. In some examples that may be combined with other examples, the first gas 184 is at least partially diverted by the second gas 186 to flow through the second apertures 164 of the showerhead 160 into the exhaust channel 314. Then, the first gas 184 flows to the exhaust conduit (118, FIG. 1). In some examples that may be combined with other examples, the first gas 184 and the second gas 186 commingle, and flow through the second apertures 164 of the showerhead 160 into the exhaust channel 314. Then, the first gas 184 and the second gas 186 flow to the exhaust conduit 118.

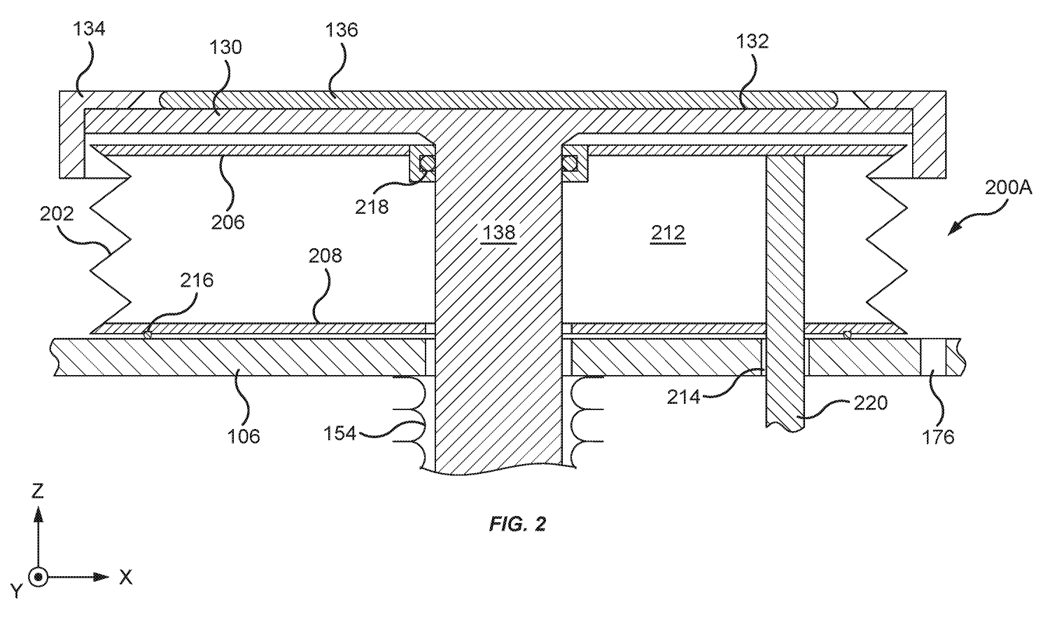

FIG. 2 schematically illustrates another embodiment of the bellows assembly 200. Bellows assembly 200A includes the top plate 206 and the outer bellows sidewall 202 that is disposed closer to the one or more chamber sidewalls 104 than to the shaft 138, but the inner bellows sidewall 204 is omitted. In some embodiments that may be combined with other embodiments, the outer bellows sidewall 202 is sealingly coupled to the floor 106. In some examples, the outer bellows sidewall is coupled to the bottom plate 208 that is sealingly coupled to the floor 106, such as via seal 216. In some other examples, the bottom plate 208 is omitted, and the outer bellows sidewall 202 is sealingly coupled directly to the floor 106.

In some embodiments that may be combined with other embodiments, the top plate 206 is fixed to the shaft 138, such that the top plate 206 moves in the Z direction with the shaft 138. In some examples, the top plate 206 is sealingly fixed to the shaft 138. In such embodiments, the bellows shaft 220 and actuator 230 may be omitted. Additionally, the bellows vent 214 in the floor 106 may be omitted. In some embodiments that may be combined with other embodiments, the top plate 206 is movable in the Z direction relative to the shaft 138 (such as by the bellows shaft 220 and the actuator 230). In some examples, the top plate 206 is sealingly coupled to the shaft 138 via a seal 218.

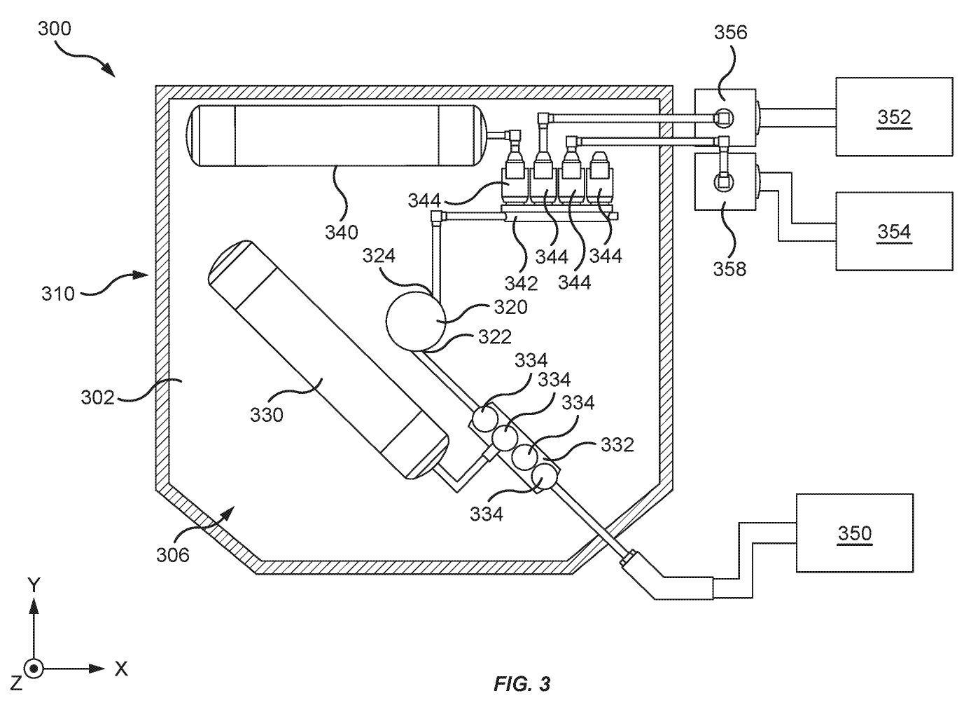

FIG. 3 schematically illustrates a top view cross-section of the lid assembly 300. A first gas reservoir 330 is disposed in the compartment 310. In some embodiments that may be combined with other embodiments, the first gas reservoir 330 contains a precursor gas, such as a molybdenum chloride. The first gas reservoir 330 is fluidically coupled to a first manifold 332 in the compartment 310, such as via a valve 334 of the first manifold 332. Each valve 334 may be fluidically coupled to a gas source, such as the first gas reservoir 330. Each valve 334 may be coupled to a gas source different from the first gas reservoir 330.

As illustrated, in some embodiments that may be combined with other embodiments, a first gas source 350 external to the compartment 310 is fluidically coupled to the first manifold 332. In some embodiments that may be combined with other embodiments, the first gas source 350 is fluidically coupled to a heater that is external to the compartment 310. In some embodiments that may be combined with other embodiments, the first gas source 350 contains a precursor gas. In some examples, the precursor gas is different from a precursor gas contained in the first gas reservoir 330. In some embodiments that may be combined with other embodiments, the first gas source 350 contains a relatively inert gas (such as N₂, Ar, or He) that is used as a purge gas or a carrier gas. In some embodiments that may be combined with other embodiments, the first gas source 350 contains a cleaning gas. In some embodiments that may be combined with other embodiments, the first gas source 350 is omitted.

The first manifold 332 is fluidically coupled to a first inlet 322 of the gas mixer 320. In some embodiments that may be combined with other embodiments, the first manifold 332 regulates gas flow into the gas mixer 320 from the first gas reservoir 330 and from other gas sources (such as the first gas source 350) that are fluidically coupled to the first manifold 332.

As illustrated, in some embodiments that may be combined with other embodiments, a second gas reservoir 340 is disposed in the compartment 310. In some embodiments that may be combined with other embodiments, the second gas reservoir 340 contains a precursor gas (such as a precursor gas the same as, or different from, a precursor gas contained in the first gas reservoir 330). In some embodiments that may be combined with other embodiments, the second gas reservoir 340 is fluidically coupled to the first manifold 332. As illustrated, in some embodiments that may be combined with other embodiments, the second gas reservoir 340 is fluidically coupled to a second manifold 342 in the compartment 310, such as via a valve 344 of the second manifold 342. Each valve 344 may be fluidically coupled to a gas source, such as the first gas reservoir 330 or the second gas reservoir 340. Each valve 344 may be coupled to a gas source different from the first gas reservoir 330 or the second gas reservoir 340. In some embodiments that may be combined with other embodiments, the second gas reservoir 340 is omitted.

As illustrated, in some embodiments that may be combined with other embodiments, a second gas source 352 external to the compartment 310 is fluidically coupled to the second manifold 340. In some embodiments that may be combined with other embodiments, the second gas source 352 contains a precursor gas. In some examples, the precursor gas is different from a precursor gas contained in the first gas reservoir 330 or the second gas reservoir 340. In some embodiments that may be combined with other embodiments, the second gas source 352 contains a relatively inert gas (such as N₂, Ar, or He) that is used as a purge gas or a carrier gas. In some embodiments that may be combined with other embodiments, the second gas source 352 contains a cleaning gas.

As illustrated, in some embodiments that may be combined with other embodiments, the second gas source 352 is fluidically coupled to a heater 356 that is external to the compartment 310. Gas flows to the second manifold 340 from the second gas source 352 via the heater 356. The heater 356 heats the gas from the second gas source 352. In some embodiments that may be combined with other embodiments, the heater 356 is omitted. In some embodiments that may be combined with other embodiments, the second gas source 352 is omitted.

As illustrated, in some embodiments that may be combined with other embodiments, a third gas source 354 external to the compartment 310 is fluidically coupled to the second manifold 340. In some embodiments that may be combined with other embodiments, the third gas source 354 contains a precursor gas. In some examples, the precursor gas is different from a precursor gas contained in the first gas reservoir 330 or the second gas reservoir 340. In some embodiments that may be combined with other embodiments, the third gas source 354 contains a relatively inert gas (such as N₂, Ar, or He) that is used as a purge gas or a carrier gas. In some embodiments that may be combined with other embodiments, the third gas source 354 contains a cleaning gas.

As illustrated, in some embodiments that may be combined with other embodiments, the third gas source 354 is fluidically coupled to a heater 358 that is external to the compartment 310. Gas flows to the second manifold 340 from the third gas source 354 via the heater 358. The heater 358 heats the gas from the third gas source 354. In some embodiments that may be combined with other embodiments, the heater 358 is omitted. In some embodiments that may be combined with other embodiments, the third gas source 354 is omitted.

The second manifold 342 is fluidically coupled to a second inlet 324 of the gas mixer 320. In some embodiments that may be combined with other embodiments, the second manifold 342 regulates gas flow into the gas mixer 320 from the second gas reservoir 340 and from other gas sources (such as the second gas source 352 or the third gas source 354) that are fluidically coupled to the second manifold 342.

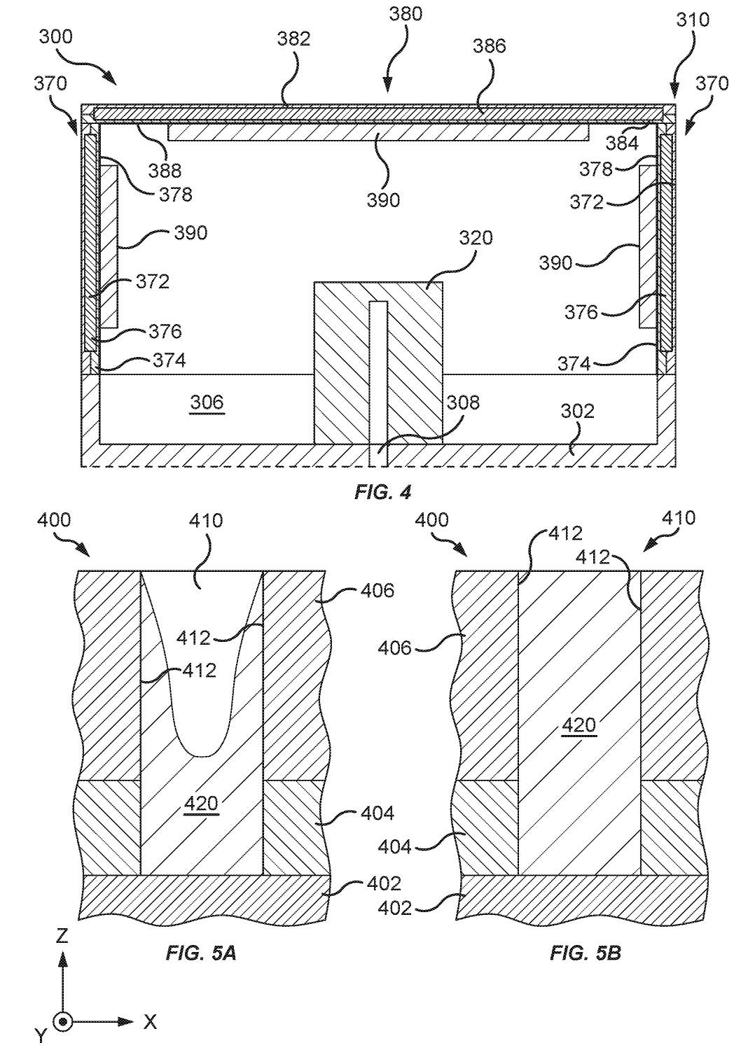

FIG. 4 schematically illustrates a side view cross-section of the lid assembly 300. Components such as the first gas reservoir 330, the second gas reservoir 340, the first manifold 332, the second manifold 342, and associated pipework have been omitted for clarity. The compartment 310 includes one or more compartment sidewalls 370 that extend from the lid plate 302 to a ceiling 380. The one or more compartment sidewalls 370 are coupled to the lid plate 302 around the recess 306 of the lid plate 302. In some embodiments that may be combined with other embodiments, any one or more of the first gas reservoir 330, the second gas reservoir 340, the first manifold 332, or the second manifold 342 are disposed at least partially in the recess 306.

In some embodiments that may be combined with other embodiments, each of the one or more compartment sidewalls 370 includes an outer layer 372 and an inner layer 374. In some examples that may be combined with other examples, an insulation layer 376 including a heat-insulating material (such as a polymeric foam, expanded polystyrene, or the like) is sandwiched between the outer layer 372 and the inner layer 374. In some examples that may be combined with other examples, the insulation layer 376 is omitted. In some examples that may be combined with other examples, the outer layer 372 or the inner layer 374 includes a heat-insulating material (such as a polymeric foam, expanded polystyrene, or the like). In some examples that may be combined with other examples, the inner layer 374 includes a heat-reflective material (such as aluminized fiberglass). In some examples that may be combined with other examples, a heat-reflective material 378 (such as an aluminized fiberglass sheet or coating) is disposed on the inner layer 374 in the compartment 310.

In some embodiments that may be combined with other embodiments, the ceiling 380 includes an outer layer 382 and an inner layer 384. In some examples that may be combined with other examples, an insulation layer 386 including a heat-insulating material (such as a polymeric foam, expanded polystyrene, or the like) is sandwiched between the outer layer 382 and the inner layer 384. In some examples that may be combined with other examples, the insulation layer 386 is omitted. In some examples that may be combined with other examples, the outer layer 382 or the inner layer 384 includes a heat-insulating material (such as a polymeric foam, expanded polystyrene, or the like). In some examples that may be combined with other examples, the inner layer 384 includes a heat-reflective material (such as aluminized fiberglass). In some examples that may be combined with other examples, a heat-reflective material 388 (such as an aluminized fiberglass sheet or coating) is disposed on the inner layer 384 in the compartment 310.

In some embodiments that may be combined with other embodiments, one or more heaters 390 are disposed in the compartment 310. In some examples that may be combined with other examples, a heater 390 of the one or more heaters 390 is disposed on one of the one or more compartment sidewalls 370. In some examples that may be combined with other examples, more than one of the one or more compartment sidewalls 370 has a heater 390 disposed thereon. In some examples that may be combined with other examples, a heater 390 of the one or more heaters 390 is disposed on the ceiling 380. In some embodiments that may be combined with other embodiments, operation of the one or more heaters 390 is controlled by the controller (180, FIG. 1).

In some embodiments that may be combined with other embodiments, the one or more heaters 390 regulate a temperature within the compartment 310. In some examples, pipework within the compartment 310 (such as connecting to the first manifold 332, the second manifold 342, or the gas mixer 320) is devoid of insulation.

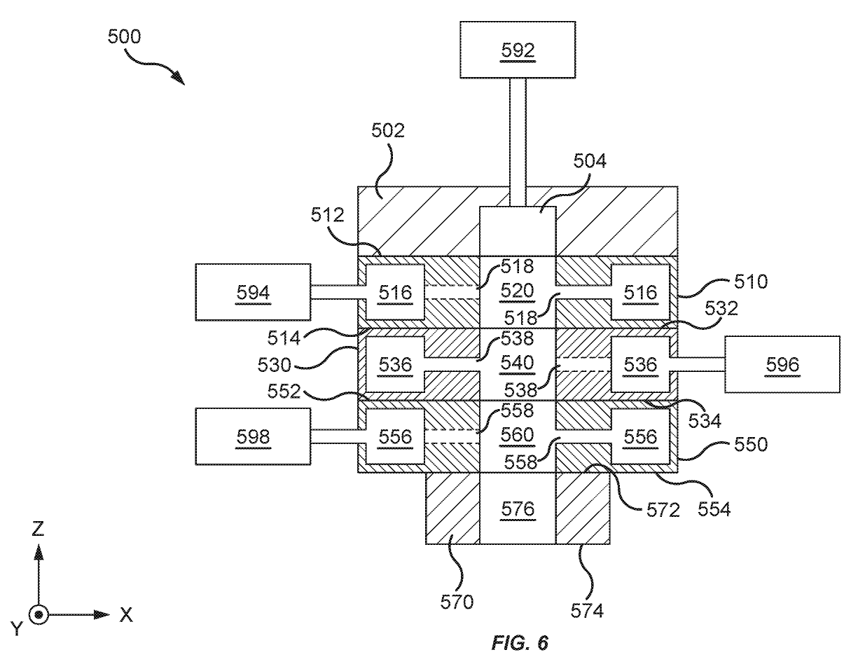

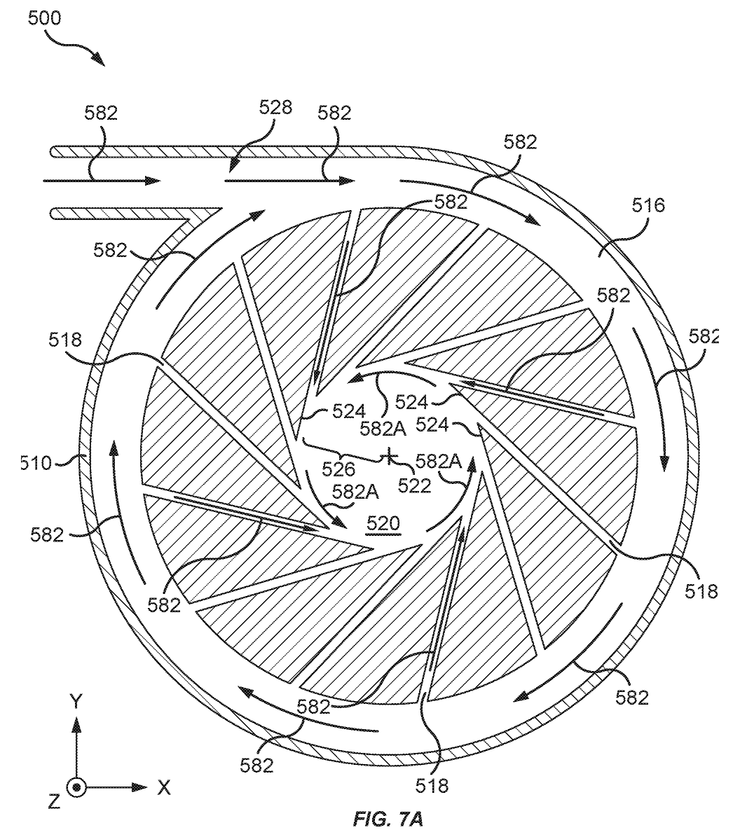

FIGS. 5A and 5B schematically illustrate a deposition operation conducted in the processing chamber 100 incorporating the lid assembly 300 compared to a deposition operation conducted in a conventional processing chamber. FIGS. 5A and 5B show a portion of a substrate 400 in which a via 410 extends through one or more dielectric layers 404, 406 (two are shown) to a base layer 402 that is metallic (such as tungsten). The deposition operations involve filling the via 410 with a fill material 420 (such as molybdenum).

FIG. 5A shows a result of a deposition operation of the fill material 420 in the via 410 conducted in a conventional processing chamber. There is preferential deposition of the fill material 420 on the sides 412 of the via 410. In some examples, the result is an incomplete deposition of the fill material 420 in the via 410. For example, deposition of the fill material 420 at the sides 412 of the via 410 can form a bridge in the via 410, leaving a portion of the via 410 below the bridge unfilled.

Without being bound by theory, it is contemplated that having the source of the precursor for the fill material 420, the source of the purge gas, and the associated control valving located external to the conventional processing chamber results in difficulties in controlling the deposition operation. For example, at the beginning of a deposition cycle, the concentration of precursor gas arriving into the processing volume of the conventional processing chamber starts at a relatively small level, then ramps up to a desired level. It has been found that when the concentration of precursor gas is at the desired level, deposition of the fill material 420 in the via 410 onto the dielectric layers 404, 406 forming the sides 412 of the via 410 is counteracted by etching of the fill material 420. Additionally, it has been found that deposition of the fill material 420 in the via 410 onto the base layer 402 or onto the fill material 420 on the base layer 402 is not so greatly counteracted. However, when the concentration of precursor gas is below the desired level, such selectivity is reduced, and the fill material 420 deposited onto the sides 412 of the via 410 remains in place, resulting in the effect shown in FIG. 5A.

FIG. 5B shows a result of a deposition operation of the fill material 420 in the via 410 conducted in the processing chamber 100. The fill material 420 fills the via 410 without the extent of preferential deposition onto the sides 412 of the via 410 as seen with the conventional processing chambers. Having the first gas reservoir 330 and the corresponding first manifold 332 in the lid assembly 300 facilitates delivery of the precursor gas into the processing volume 108 at the desired level of concentration from the beginning of each deposition cycle, and the detrimental deposition profile depicted in FIG. 5A can be avoided.

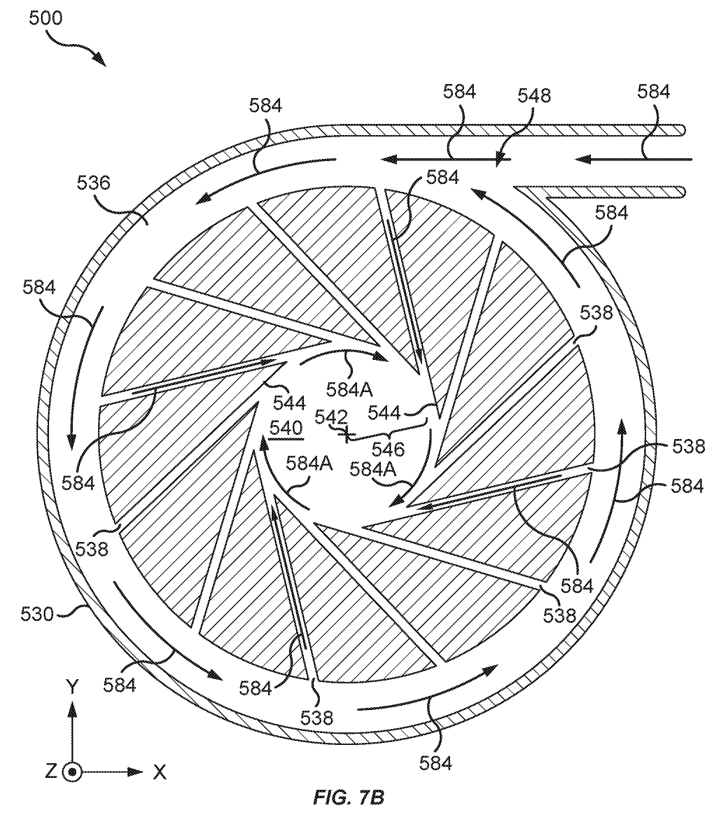

FIG. 6 schematically illustrates an embodiment of the gas mixer 320. The gas mixer 320 is represented by gas mixer 500. In some embodiments that may be combined with other embodiments, the gas mixer 500 includes a cap 502. In some embodiments that may be combined with other embodiments, the cap 502 includes a cap conduit 504. The cap conduit 504 is configured to be fluidically coupled to a gas supply 592 (such as first gas source 350, second gas source 354, third gas source 356, first gas reservoir 330, or second gas reservoir 340). In some examples, the cap conduit 504 is configured to be fluidically coupled to the first manifold 332 or the second manifold 342. In some embodiments that may be combined with other embodiments, the cap conduit 504 is sealed closed at the cap 502. In some embodiments that may be combined with other embodiments, the cap conduit 504 is omitted. In some embodiments that may be combined with other embodiments, the cap 502 is omitted.

In embodiments in which the cap 502 is present, the cap 502 is coupled to a first mixer unit 510. The first mixer unit 510 includes a first annular channel 516. The first annular channel 516 is configured to be fluidically coupled to a gas supply 594 (such as first gas source 350, second gas source 352, third gas source 354, first gas reservoir 330, or second gas reservoir 340). In some examples, the first annular channel 516 is configured to be fluidically coupled to the first manifold 332 or the second manifold 342.

The first annular channel 516 surrounds a first conduit 520. As illustrated, in some embodiments that may be combined with other embodiments, the first conduit 520 extends from a top 512 of the first mixer unit 510 to a bottom 514 of the first mixer unit 510. In embodiments in which the cap 502 with the cap conduit 504 is present, the first conduit 520 is fluidically coupled with the cap conduit 504. In embodiments in which the cap 502 is omitted, the first conduit 520 is closed at the top 512 of the first mixer unit 510. A plurality of first ducts 518 fluidically couples the first annular channel 516 with the first conduit 520.

The gas mixer 500 includes a second mixer unit 530 coupled to the first mixer unit 510. The second mixer unit 530 includes a second annular channel 536. The second annular channel 536 is configured to be fluidically coupled to a gas supply 596 (such as first gas source 350, second gas source 352, third gas source 354, first gas reservoir 330, or second gas reservoir 340). In some examples, the second annular channel 536 is configured to be fluidically coupled to the first manifold 332 or the second manifold 342.

The second annular channel 536 surrounds a second conduit 540. The second conduit 540 extends from a top 532 of the second mixer unit 530 to a bottom 534 of the second mixer unit 530. The second conduit 540 is fluidically coupled with the first conduit 520. A plurality of second ducts 538 fluidically couples the second annular channel 536 with the second conduit 540.

In some embodiments that may be combined with other embodiments, the gas mixer 500 includes a third mixer unit 550 coupled to the second mixer unit 530. The third mixer unit 550 includes a third annular channel 556. The third annular channel 556 is configured to be fluidically coupled to a gas supply 598 (such as first gas source 350, second gas source 352, third gas source 354, first gas reservoir 330, or second gas reservoir 340). In some examples, the third annular channel 556 is configured to be fluidically coupled to the first manifold 332 or the second manifold 342.

The third annular channel 556 surrounds a third conduit 560. The third conduit 560 extends from a top 552 of the third mixer unit 550 to a bottom 554 of the third mixer unit 550. The third conduit 560 is fluidically coupled with the second conduit 540. A plurality of third ducts 558 fluidically couples the third annular channel 556 with the third conduit 560.

In some embodiments that may be combined with other embodiments, the third mixer unit 550 is omitted. In some embodiments that may be combined with other embodiments, the gas mixer 500 includes one or more additional mixer units coupled below the third mixer unit 550. The one or more additional mixer units may be configured similarly to any of the first mixer unit 510, the second mixer unit 530, or the third mixer unit 550.

As illustrated, in some embodiments that may be combined with other embodiments, the third mixer unit 550 is coupled to an adapter 570. The adapter 570 includes an adapter conduit 576 that extends from a top 572 of the adapter 570 to a bottom 574 of the adapter 570. The adapter conduit 576 is fluidically coupled with the third conduit 560. When installed on the lid plate (302, FIG. 1), the adapter conduit 576 is fluidically coupled with the conduit (308, FIG. 1) through the lid plate 302. The cap conduit 504 (when present), the first conduit 520, the second conduit 540, and the third conduit 560 (when present) are fluidically coupled to the conduit 308 through the lid plate 302 via the adapter conduit 576.

In some embodiments that may be combined with other embodiments, the adapter 570 is omitted. In some examples, the lid plate 302 includes an adapter configured to couple to the gas mixer 500. In such examples, the cap conduit 504 (when present), the first conduit 520, the second conduit 540, and the third conduit 560 (when present) are fluidically coupled to the conduit 308 through the lid plate 302 via a conduit through the adapter of the lid plate 302.

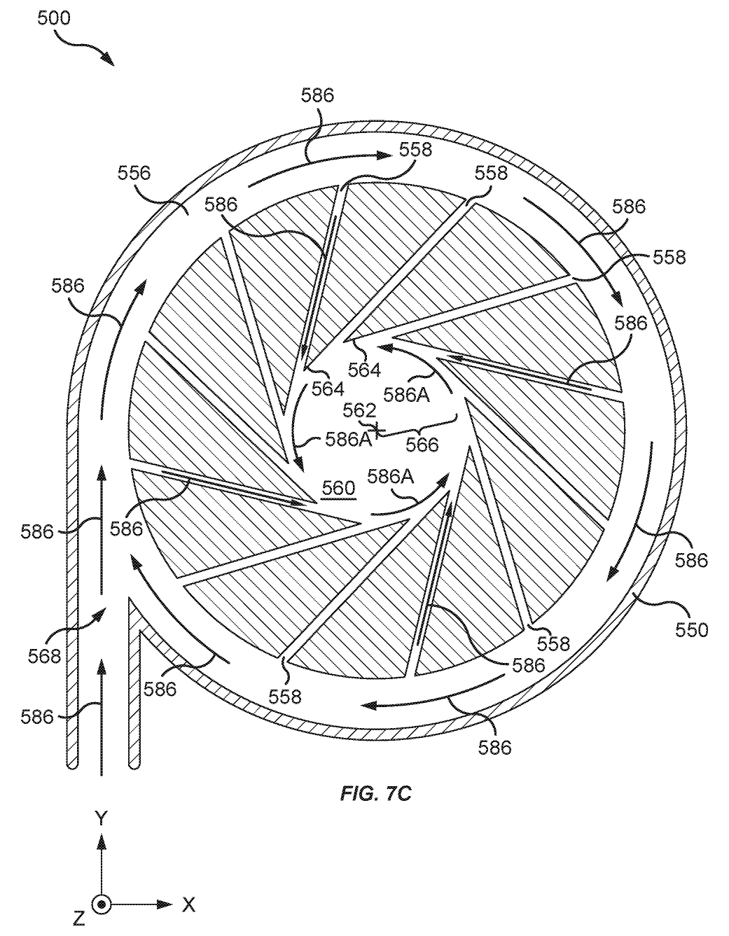

FIG. 7A schematically illustrates a first gas flow through the first mixer unit 510. The first gas flow is represented by arrows 582. The first gas 582 flows into the first mixer unit 510 via a first inlet 528, and enters the first annular channel 516. The first gas 582 flows in the first annular channel 516, and enters the first ducts 518. Each first duct 518 is oriented to direct the first gas flow 582 from the first annular channel 516 into the first conduit 520 in a first rotational direction (represented by arrows 582A) about a center 522 of the first conduit 520. In some embodiments, the first rotational direction 582A is clockwise. In some embodiments, the first rotational direction 582A is anticlockwise.

In some examples that may be combined with other examples, each first duct 518 is oriented to direct the first gas flow 582 from the first annular channel 516 into the first conduit 520 away from the center 522 of the first conduit 520 (i.e. in an off-center direction). In some examples that may be combined with other examples, each first duct 518 is oriented to direct the first gas flow 582 towards a zone 526 between the center 522 of the first conduit 520 and a wall 524 of the first conduit 520. In some examples, each first duct 518 is oriented to direct the first gas flow 582 tangentially with respect to the wall 524 of the first conduit 520.

FIG. 7B schematically illustrates a second gas flow through the second mixer unit 530. The second gas flow is represented by arrows 584. The second gas 584 flows into the second mixer unit 530 via a second inlet 548, and enters the second annular channel 536. The second gas 584 flows in the second annular channel 536, and enters the second ducts 538. Each second duct 538 is oriented to direct the second gas flow 584 from the second annular channel 536 into the second conduit 540 in a second rotational direction (represented by arrows 584A) about a center 542 of the second conduit 540. The second rotational direction 584A is opposite the first rotational direction 582A (anticlockwise or clockwise, as appropriate).

In some examples that may be combined with other examples, each second duct 538 is oriented to direct the second gas flow 584 from the second annular channel 536 into the second conduit 540 away from the center 542 of the second conduit 540 (i.e. in an off-center direction). In some examples that may be combined with other examples, each second duct 538 is oriented to direct the second gas flow 584 towards a zone 546 between the center 542 of the second conduit 540 and a wall 544 of the second conduit 540. In some examples, each second duct 538 is oriented to direct the second gas flow 584 tangentially with respect to the wall 544 of the second conduit 540.

FIG. 7C schematically illustrates a third gas flow through the third mixer unit 550. The third gas flow is represented by arrows 586. The third gas 586 flows into the third mixer unit 550 via a third inlet 568, and enters the third annular channel 556. The third gas 586 flows in the third annular channel 556, and enters the third ducts 558. Each third duct 558 is oriented to direct the third gas flow 586 from the third annular channel 556 into the third conduit 560 in a third rotational direction (represented by arrows 586A) about a center 562 of the third conduit 560. In some embodiments that may be combined with other embodiments, the third rotational direction 586A is opposite the first rotational direction 582A. In some embodiments that may be combined with other embodiments, the third rotational direction 586A is opposite the second rotational direction 584A.

In some examples that may be combined with other examples, each third duct 558 is oriented to direct the third gas flow 586 from the third annular channel 556 into the third conduit 560 away from the center 562 of the third conduit 560 (i.e. in an off-center direction). In some examples that may be combined with other examples, each third duct 558 is oriented to direct the third gas flow 586 towards a zone 566 between the center 562 of the third conduit 560 and a wall 564 of the third conduit 560. In some examples that may be combined with other examples, each third duct 558 is oriented to direct the third gas flow 586 tangentially with respect to the wall 564 of the third conduit 560.

The first gas flow 582/582A in the first conduit 520 forms a first vortex as the first gas 582 flows through the first conduit 520. The second gas flow 584/584A in the second conduit 540 forms a second vortex as the second gas 586 flows through the second conduit 540. As the first gas 582/582A flows from the first conduit 520 into the second conduit 540, the first vortex interacts with the second vortex. Because the first vortex rotates in the first direction and the second vortex rotates in the second direction opposite the first direction, the interaction between the first vortex and the second vortex promotes mixing together of the first gas 582/582A and the second gas 584/584A.

Depending on such aspects as the relative flow rates, concentrations, or densities of the first gas 582 and the second gas 584, the combined first gas 582 and second gas 584 may flow through the second conduit 540 in a combined vortex that rotates in the first direction or in the second direction. In some embodiments, the combined first gas 582 and second gas 584 may flow through the second conduit 540 in a turbulent flow regime that does not form a vortex.

The third gas flow 586/586A in the third conduit 560 forms a third vortex as the third gas 586 flows through the third conduit 560. As the combined first gas 582 and second gas 584 flows from the second conduit 540 into the third conduit 560, the third vortex interacts with the combined first gas 582 and second gas 584. In embodiments in which the combined first gas 582 and second gas 584 flows into the third conduit 560 in a turbulent flow regime that does not form a vortex (or in a vortex that rotates opposite the third direction), the interaction between the combined first gas 582 and second gas 584 and the third vortex promotes mixing together of the first gas 582 and the second gas 584 with the third gas 586.

The interactions described above between the first gas 582, the second gas 584, and the third gas 586 promote a homogeneity of mixing together the first gas582, the second gas 584, and the third gas 586 that is greater than is achieved from an interaction between vortices of the first gas 582, the second gas 584, and the third gas 586 rotating in the same direction.

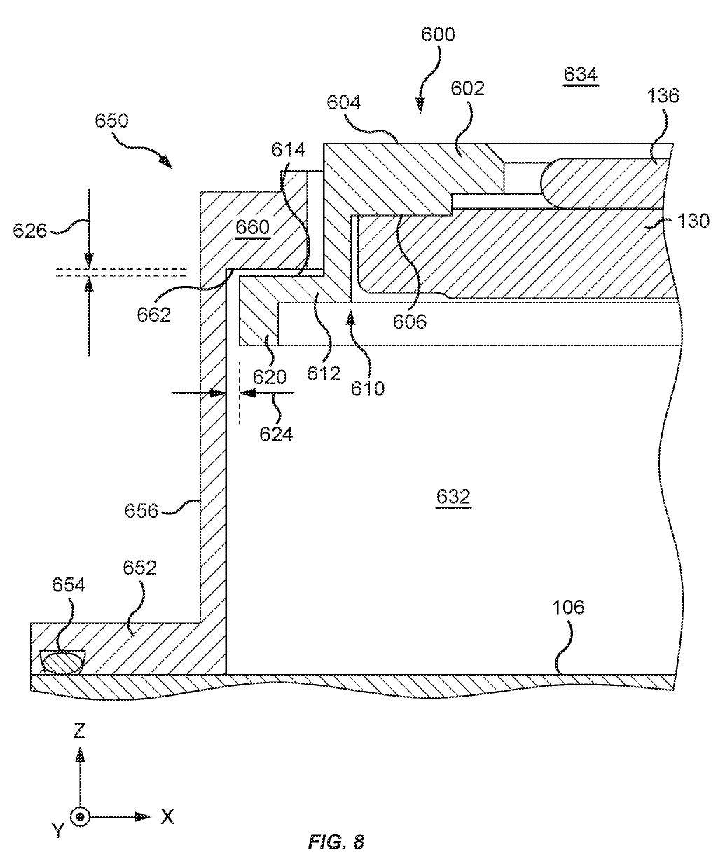

FIG. 8 schematically illustrates a portion of an embodiment of the edge ring 134 and an embodiment of the liner 112 that may be used together in the processing chamber 100. The edge ring 134 is represented by edge ring 600, and the liner 112 is represented by liner 650.

The edge ring 600 is shown disposed on the substrate support 130, and includes an annular body 602 that encircles the substrate 136 in the X-Y plane. The body 602 includes a top surface 604 and a bottom surface 606. The edge ring 600 includes a skirt 610 that extends downwardly along the Z direction from the bottom surface 606 of the body 602. In some embodiments that may be combined with other embodiments, the skirt 610 is annular, and encircles the substrate support 130 in the X-Y plane.

The skirt 610 includes a step 612 that extends outwardly in the X-Y plane such that an outer diameter of the step 612 is greater than an outer diameter of the body 602. The step 612 includes a top surface 614. A level of the top surface 614 of the step 612 along the Z direction is below a level of the top surface 604 of the body 602 along the Z direction. In some embodiments that may be combined with other embodiments, the step 612 is annular. In some embodiments that may be combined with other embodiments, the skirt 610 includes a tail section 620 extending downwardly along the Z direction from the step 612. In some embodiments that may be combined with other embodiments, the tail section 620 is annular.

The liner 650 includes a base 652. As illustrated, in some embodiments that may be combined with other embodiments, the base 652 can be disposed on the floor 106 of the processing chamber 100. In some embodiments that may be combined with other embodiments, the base 652 is annular. In some embodiments that may be combined with other embodiments, a seal 654 hinders fluid migration between the base 652 of the liner 650 and the floor 106.

The liner 650 includes a sleeve 656 extending upwardly along the Z direction from the base 652. In some embodiments that may be combined with other embodiments, at least a portion of the sleeve 656 is annular. A ledge 660 extends inwardly in the X-Y plane from the sleeve 656 towards the edge ring 600. The ledge 660 includes a bottom surface 662 that at least partially overlaps the top surface 614 of the step 612. In some embodiments that may be combined with other embodiments, a distance 624 between an inner surface of the sleeve 656 and an outer surface of the step 612 is greater than a distance 626 between a bottom surface 662 of the ledge 660 and the top surface 614 of the step 612. In some embodiments that may be combined with other embodiments, the distance 626 is 3 mm or less, such as 2 mm or less, 1 mm or less, 0.5 mm or less, 0.25 mm or less, or 0.1 mm or less.

The juxtaposition between the step 612 of the edge ring 600 and the ledge 660 of the liner 650 presents a choke to the flow of a purge gas flowing between the step 612 and the ledge 660 from a zone 632 below the substrate support 130 to a zone 634 above the substrate support 130. In some embodiments that may be combined with other embodiments, the distance 626 is selected according to a desired pressure drop between the zone 632 below the substrate support 130 and the zone 634 above the substrate support 130. In some examples that may be combined with other examples, the pressure drop is 0.5 Torr or greater, such as 1 Torr or greater, 1.5 Torr or greater, 2 Torr or greater, 2.5 Torr or greater, 3 Torr or greater. 3.5 Torr or greater, 4 Torr or greater, 4.5 Torr or greater, 5 Torr or greater, 5.5 Torr or greater, 6 Torr or greater. 6.5 Torr or greater, or 7 Torr or greater.

In some embodiments that may be combined with other embodiments, the distance 626 is selected according to a desired velocity of the purge gas flowing from the zone 632 below the substrate support 130 to the zone 634 above the substrate support 130. In some examples that may be combined with other examples, the velocity is 5 m/s or greater, such as 7 m/s or greater, 10 m/s or greater, 15 m/s or greater, 20 m/s or greater, 25 m/s or greater, or 30 m/s or greater.

The juxtaposition between the step 612 of the edge ring 600 and the ledge 660 of the liner 650 represents an improvement on conventional systems in excluding process gases migrating from the zone 634 to the zone 632. Some conventional systems rely predominantly on pressure difference alone between the zone 632 and the zone 634 in an attempt to hinder migration of process gases into the zone 632. However, mixing of the process gases with the purge gases can occur, resulting in some migration of the process gases into the zone 632.

Some conventional systems rely on the distance 624 between the inner surface of the sleeve 656 and an outer surface of the edge ring (134, FIG. 1) to hinder migration of process gases into the zone 632. However, dimensional tolerances necessary to avoid inadvertently impeding the passage of the substrate support 130 and edge ring 134 through the liner (112, FIG. 1) along the Z direction render the distance 624 ineffective as a choke.

In contrast, the distance 626 between the bottom surface 662 of the ledge 660 of the liner 650 and the top surface of the step 612 of the edge ring 600 can be precisely controlled when raising the substrate support 130 along the Z direction to prepare for processing the substrate 136. The pressure drop and flowrate of the purge gas facilitated by the juxtaposition between the step 612 of the edge ring 600 and the ledge 660 of the liner 650 hinder mixing of the process gases and the purge gas at the top surface 614 of the step 612, and hinder migration of the process gases into the zone 632.

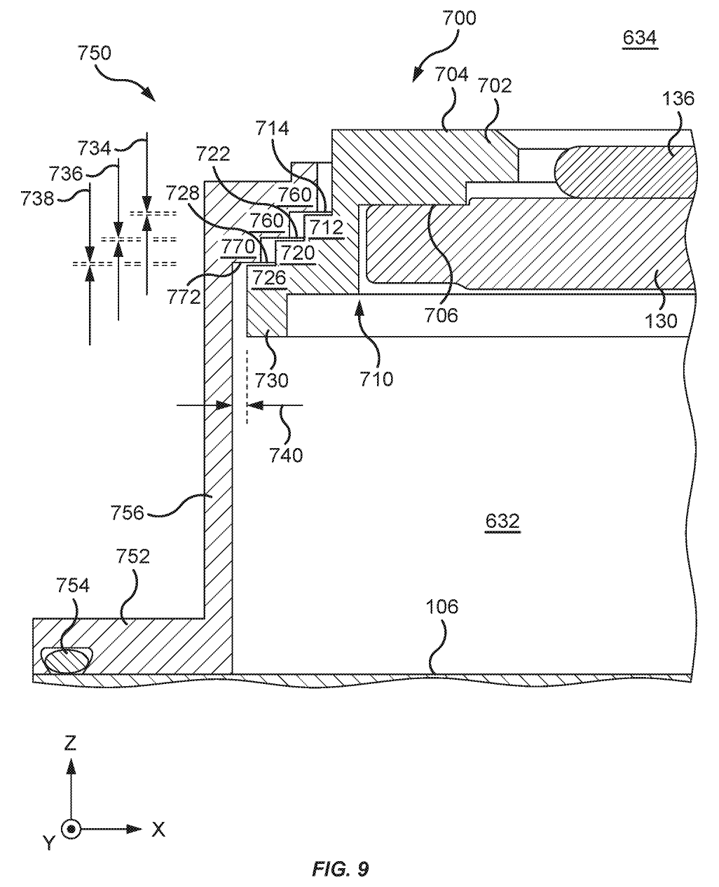

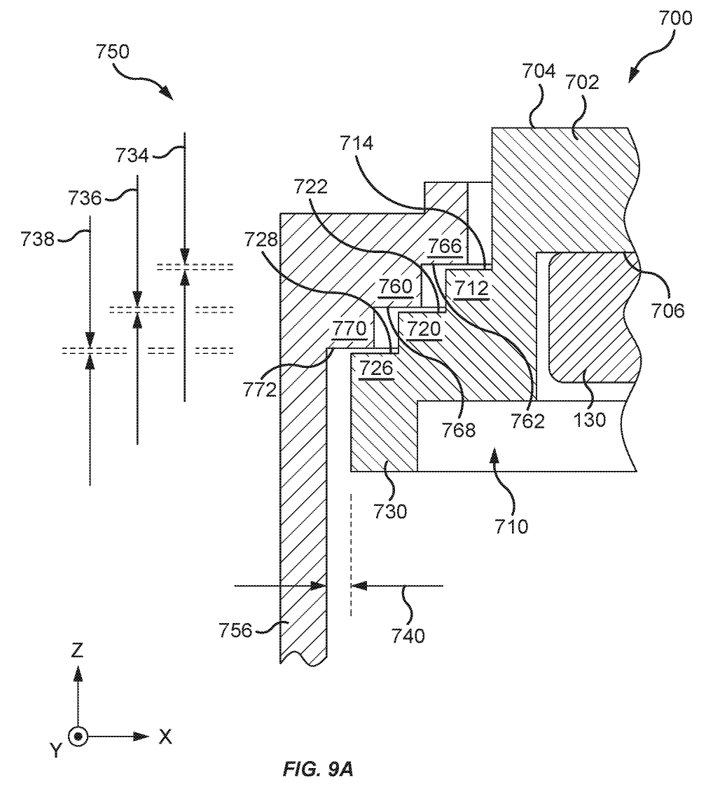

FIG. 9 schematically illustrates a portion of an embodiment of the edge ring 134 and an embodiment of the liner 112 that may be used together in the processing chamber 100. FIG. 9A is an enlargement of a portion of FIG. 9. The edge ring 134 is represented by edge ring 700, and the liner 112 is represented by liner 750.

The edge ring 700 is shown disposed on the substrate support 130, and includes an annular body 702 that encircles the substrate 136 in the X-Y plane. The body 702 includes a top surface 704 and a bottom surface 706. The edge ring 700 includes a skirt 710 that extends downwardly along the Z direction from the bottom surface 706 of the body 702. In some embodiments that may be combined with other embodiments, the skirt 710 is annular, and encircles the substrate support 130 in the X-Y plane.

The skirt 710 includes a first step 712 that extends outwardly in the X-Y plane such that an outer diameter of the first step 712 is greater than an outer diameter of the body 702. The first step 712 includes a top surface 714. A level of the top surface 714 of the first step 712 along the Z direction is below a level of the top surface 704 of the body 702 along the Z direction. In some embodiments that may be combined with other embodiments, the first step 712 is annular.

The skirt 710 includes a second step 720 that extends outwardly in the X-Y plane below the first step 712 such that an outer diameter of the second step 720 is greater than an outer diameter of the first step 712. The second step 720 includes a top surface 722. A level of the top surface 722 of the second step 720 along the Z direction is below the level of the top surface 714 of the first step 712 along the Z direction. In some embodiments that may be combined with other embodiments, the second step 720 is annular.

In some embodiments that may be combined with other embodiments, the skirt 710 includes a third step 726 that extends outwardly in the X-Y plane below the second step 720 such that an outer diameter of the third step 726 is greater than an outer diameter of the second step 720. The third step 726 includes a top surface 728. A level of the top surface 728 of the third step 726 along the Z direction is below the level of the top surface 722 of the second step 720 along the Z direction. In some embodiments that may be combined with other embodiments, the third step 726 is annular. Although three steps are depicted, it is contemplated that the edge ring may include a different number of steps, such as two, four, five, or more.

In some embodiments that may be combined with other embodiments, the skirt 710 includes a tail section 730 extending downwardly along the Z direction from the third step 726. In some embodiments that may be combined with other embodiments, the tail section 730 is annular.

The liner 750 includes a base 752. As illustrated, in some embodiments that may be combined with other embodiments, the base 752 can be disposed on the floor 106 of the processing chamber 100. In some embodiments that may be combined with other embodiments, the base 752 is annular. In some embodiments that may be combined with other embodiments, a seal 754 hinders fluid migration between the base 752 of the liner 750 and the floor 106.

The liner 750 includes a sleeve 756 extending upwardly along the Z direction from the base 752. In some embodiments that may be combined with other embodiments, at least a portion of the sleeve 756 is annular. A first ledge 760 extends inwardly in the X-Y plane from the sleeve 756 towards the edge ring 700. The first ledge 760 includes a bottom surface 762 that at least partially overlaps the top surface 714 of the first step 712. In some embodiments that may be combined with other embodiments, a distance 740 between an inner surface of the sleeve 756 and an outer surface of the third step 726 is greater than a distance 734 between the bottom surface 762 of the first ledge 760 and the top surface 714 of the first step 712. In some embodiments that may be combined with other embodiments, the distance 734 is 3 mm or less, such as 2 mm or less, 1 mm or less, 0.5 mm or less, 0.25 mm or less, or 0.1 mm or less.

A second ledge 766 extends inwardly in the X-Y plane from the sleeve 756 towards the edge ring 700. The second ledge 766 is below the first ledge 760 along the Z direction, and extends from the sleeve 756 by a lesser degree than the first ledge 760. The second ledge 766 includes a bottom surface 768 that at least partially overlaps the top surface 722 of the second step 720. In some embodiments that may be combined with other embodiments, the distance 740 between the inner surface of the sleeve 756 and the outer surface of the third step 726 is greater than a distance 736 between the bottom surface 768 of the second ledge 766 and the top surface 722 of the second step 720. In some embodiments that may be combined with other embodiments, the distance 736 is 3 mm or less, such as 2 mm or less, 1 mm or less, 0.5 mm or less, 0.25 mm or less, or 0.1 mm or less.

In some embodiments that may be combined with other embodiments, a third ledge 770 extends inwardly in the X-Y plane from the sleeve 756 towards the edge ring 500. The third ledge 770 is below the second ledge 766 along the Z direction, and extends from the sleeve 756 by a lesser degree than the second ledge 766. The third ledge 770 includes a bottom surface 772 that at least partially overlaps the top surface 728 of the third step 726. In some embodiments that may be combined with other embodiments, the distance 740 between the inner surface of the sleeve 756 and the outer surface of the third step 726 is greater than a distance 738 between the bottom surface 772 of the third ledge 770 and the top surface 728 of the third step 726. In some embodiments that may be combined with other embodiments, the distance 738 is 3 mm or less, such as 2 mm or less, 1 mm or less, 0.5 mm or less, 0.25 mm or less, or 0.1 mm or less.

Although three ledges are depicted, it is contemplated that the liner 750 may include a different number of ledges, such as two, four, five, or more. The steps of the edge ring 700 and the ledges of the liner 750 are correspondingly staggered. In some embodiments that may be combined with other embodiments, the number of ledges of the liner 750 equals the number of steps of the edge ring 700. In some embodiments that may be combined with other embodiments, the number of ledges of the liner 750 is greater than the number of steps of the edge ring 700. In some embodiments that may be combined with other embodiments, the number of ledges of the liner 750 is less than the number of steps of the edge ring 700.

It is contemplated that the configuration of steps of the edge ring 700 juxtaposed with corresponding ledges of the liner 750 provides similar operational effects and benefits as does the configuration of the step 712 of the edge ring 600 juxtaposed with the ledge 600 of the liner 650.

The systems, apparatus, and methods of the present disclosure provide for improved control of substrate processing operations and improved product quality compared to conventional processing chambers and methods.

The subject matter of the present disclosure can be expressed in one or more of the following Examples:

Example 1: A gas mixer for a substrate processing chamber, the gas mixer comprising:
a first mixer unit comprising:
   a first annular channel surrounding a first conduit; and
   a plurality of first ducts fluidically coupling the first annular channel with the first conduit, each first duct oriented to direct a first gas flow from the first annular channel into the first conduit in a clockwise direction about a center of the first conduit; and
a second mixer unit comprising:
   a second annular channel surrounding a second conduit, the second conduit aligned with the first conduit; and
   a plurality of second ducts fluidically coupling the second annular channel with the second conduit, each second duct oriented to direct a second gas flow from the second annular channel into the second conduit in an anticlockwise direction about a center of the second conduit.

Example 2:
The gas mixer of Example 1, wherein:
   each first duct is oriented to direct the first gas flow tangentially with respect to a wall of the first conduit; and
   each second duct is oriented to direct the second gas flow tangentially with respect to a wall of the second conduit.

Example 3:
The gas mixer of Example 1, wherein:
   the plurality of first ducts is disposed around the first conduit; and
   the plurality of second ducts is disposed around the second conduit.

Example 4: The gas mixer of Example 1, wherein the first mixer unit is disposed adjacent the second mixer unit.

Example 5:
The gas mixer of Example 1, further comprising:
   a third mixer unit comprising: a third annular channel surrounding a third conduit, the third conduit aligned with the first conduit; and
   a plurality of third ducts fluidically coupling the third annular channel with the third conduit, each third duct oriented to direct a third gas flow from the third annular channel into the third conduit in one of a clockwise or an anticlockwise direction about a center of the third conduit.

Example 6:
The gas mixer of Example 5, wherein:
   the third mixer unit is disposed adjacent the second mixer unit; and
   each third duct is oriented to direct the third gas flow into the third conduit in the clockwise direction.

Example 7:
The gas mixer of Example 5, wherein:
   the third mixer unit is disposed adjacent the first mixer unit; and ;
   each third duct is oriented to direct the third gas flow into the third conduit in the anticlockwise direction.

Example 8:
A processing chamber comprising:
   a chamber body, including a floor and one or more chamber sidewalls;
   a showerhead coupled to the chamber body, the showerhead and chamber body enclosing a processing volume;
   a lid plate coupled to the showerhead, the lid plate and the showerhead defining a plenum therebetween;
   a gas mixer coupled to the lid plate, the gas mixer comprising:
      a first mixer unit comprising:
         a first annular channel surrounding a first conduit; and
         a plurality of first ducts fluidically coupling the first annular channel with the first conduit, each first duct oriented to direct a first gas flow from the first annular channel into the first conduit in a clockwise direction about a center of the first conduit; and
      a second mixer unit comprising:
         a second annular channel surrounding a second conduit, the second conduit aligned with the first conduit; and
         a plurality of second ducts fluidically coupling the second annular channel with the second conduit, each second duct oriented to direct a second gas flow from the second annular channel into the second conduit in an anticlockwise direction about a center of the second conduit.

Example 9:
The processing chamber of Example 8, wherein:
   each first duct is oriented to direct the first gas flow tangentially with respect to a wall of the first conduit; and
   each second duct is oriented to direct the second gas flow tangentially with respect to a wall of the second conduit.

Example 10:
The processing chamber of Example 8, wherein:
   the plurality of first ducts is disposed around the first conduit; and
   the plurality of second ducts is disposed around the second conduit.

Example 11: The processing chamber of Example 8, wherein the first mixer unit is disposed adjacent the second mixer unit

Example 12:
The processing chamber of Example 8, wherein the gas mixer further comprises:
   a third mixer unit comprising:
      a third annular channel surrounding a third conduit, the third conduit aligned with the first conduit; and
      a plurality of third ducts fluidically coupling the third annular channel with the third conduit, each third duct oriented to direct a third gas flow from the third annular channel into the third conduit in one of a clockwise or an anticlockwise direction about a center of the third conduit.

Example 13:
The processing chamber of Example 12, wherein:
   the third mixer unit is disposed adjacent the second mixer unit; and
   each third duct is oriented to direct the third gas flow into the third conduit in the clockwise direction.

Example 14:
The processing chamber of Example 12, wherein:
   the third mixer unit is disposed adjacent the first mixer unit; and
   each third duct is oriented to direct the third gas flow into the third conduit in the anticlockwise direction.

Example 15:
The processing chamber of Example 8, wherein:
   the first annular channel is fluidically coupled to a first gas supply; and
   the second annular channel is fluidically coupled to a second gas supply.

Example 16:
An edge ring for a substrate processing chamber, the edge ring comprising:
   an annular body including a top surface and a bottom surface;
   a skirt extending downwardly from the bottom surface of the annular body, the skirt including an outwardly extending first step;
   wherein a level of a top surface of the first step is below a level of the top surface of the annular body.

Example 17: The edge ring of Example 16, wherein an outer diameter of the first step is greater than an outer diameter of the annular body.

Example 18: The edge ring of Example 16, wherein the skirt further includes an annular tail section extending downwardly from the first step.

Example 19: The edge ring of Example 16, wherein the skirt further includes a second step extending outwardly below the first step.

Example 20: The edge ring of Example 19, wherein the skirt further includes an annular tail section extending downwardly from the second step.

Example 21:
An assembly for a substrate processing chamber, the assembly comprising:
   an edge ring comprising:
      an annular body including a top surface and a bottom surface; and
      a skirt extending downwardly from the bottom surface of the annular body, the skirt including an outwardly extending first step; and
   a liner comprising a sleeve and a first ledge extending inwardly from the sleeve; wherein the first ledge at least partially overlaps the first step.

Example 22: The assembly of Example 21, wherein a level of a top surface of the first step is below a level of the top surface of the annular body.

Example 23: The assembly of Example 21, wherein a distance between an inner surface of the sleeve and an outer surface of the first step is greater than a distance between a bottom surface of the first ledge and the top surface of the first step.

Example 24: The assembly of Example 21, wherein the skirt of the edge ring further includes a second step extending outwardly below the first step.

Example 25: The assembly of Example 24, wherein the liner further comprises a second ledge extending inwardly from the sleeve, the second ledge including a bottom surface at least partially overlapping the top surface of the second step.

It is contemplated that any one or more elements or features of any one disclosed embodiment or example may be beneficially incorporated in any one or more other non-mutually exclusive embodiments or examples. While the foregoing is directed to embodiments of the present disclosure, other and further embodiments of the disclosure may be devised without departing from the basic scope thereof, and the scope thereof is determined by the claims that follow.

What is claimed is:

1. A processing chamber comprising:
a chamber body, including a floor and one or more chamber sidewalls;
a showerhead coupled to the chamber body, the showerhead and chamber body enclosing a processing volume;
a lid plate coupled to the showerhead, the lid plate and the showerhead defining a plenum therebetween;
a first annular channel disposed around the lid plate, the first annular channel coupled to an exhaust conduit; and
a second annular channel disposed around at least one of the lid plate or the showerhead, the second annular channel coupled to a supply of purge gas.

2. The processing chamber of claim 1, wherein the first annular channel is disposed between the lid plate and the second annular channel.

3. The processing chamber of claim 1, further comprising a liner separating the first and second annular channels.

4. The processing chamber of claim 1, wherein the showerhead includes:
a plurality of first apertures fluidically coupling the plenum and the processing volume.

5. The processing chamber of claim 4, wherein the showerhead further includes:
a plurality of second apertures fluidically coupling the processing volume and the first annular channel.

6. The processing chamber of claim 4, wherein the plurality of second apertures surrounds the plurality of first apertures.

7. A processing chamber comprising:
a chamber body, including a floor and one or more chamber sidewalls;
a showerhead coupled to the chamber body, the showerhead and chamber body enclosing a processing volume;
a substrate support disposed in the processing volume;
a shaft coupled to the substrate support, and extending through the floor; and
a bellows assembly disposed around the shaft in the processing volume, the bellows assembly including a first bellows sidewall disposed closer to the one or more chamber sidewalls than to the shaft.

8. The processing chamber of claim 7, wherein the bellows assembly further comprises a second bellows sidewall between the shaft and the first bellows sidewall.

9. The processing chamber of claim 7, wherein the bellows assembly is movable along the shaft independently of movement of the shaft.

10. The processing chamber of claim 7, further comprising:
a first actuator coupled to the shaft, the first actuator configured to move the shaft in a vertical direction.

11. The processing chamber of claim 9, further comprising:
a second actuator coupled to the bellows assembly, the second actuator configured to extend the bellows assembly in the vertical direction.

12. The processing chamber of claim 7, wherein the bellows assembly fluidically isolates a first fluid in the processing volume from a second fluid in a bellows volume encompassed by the bellows assembly.

13. A processing chamber comprising:
a chamber body, including a floor and one or more chamber sidewalls; and
a lid assembly comprising:
a lid plate coupled to the chamber body;
a compartment disposed on the lid plate, the compartment including one or more compartment sidewalls and a ceiling;
a first manifold disposed in the compartment; and
a first gas reservoir disposed in the compartment, and fluidically coupled to the first manifold.

14. The processing chamber of claim 13, further comprising one or more heaters disposed in the compartment.

15. The processing chamber of claim 14, wherein the one or more heaters includes a first heater disposed on one of the one or more sidewalls.

16. The processing chamber of claim 15, wherein the one or more heaters includes a second heater disposed on the ceiling.

17. The processing chamber of claim 13, further comprising:
a second manifold disposed in the compartment; and
a second gas reservoir disposed in the compartment, and fluidically coupled to the second manifold.

18. The processing chamber of claim 13, further comprising a second manifold disposed in the compartment, wherein the second manifold is fluidically coupled to a second gas reservoir disposed external to the compartment.

19. The processing chamber of claim 18, wherein the second gas reservoir is fluidically coupled to a heater external to the compartment.

20. The processing chamber of claim 19, wherein the first gas reservoir contains a precursor gas, and the second gas reservoir contains a purge gas.
